(19) United States
(12) Patent Application Publication
(10) Pub. No.: US 2019/0148498 A1
(43) Pub. Date: May 16, 2019

(54) Passivation Structure For GaN Field Effect Transistor

(71) Applicant: WIN Semiconductors Corp., Tao Yuan City (TW)

(72) Inventors: Eric LEE, Tao Yuan City (TW); Yu-Kuo YANG, Tao Yuan City (TW); Che-Kai LIN, Tao Yuan City (TW); Forrest CHO, Tao Yuan City (TW); Walter Tony WOHLMUTH, Tao Yuan City (TW)

(21) Appl. No.: 15/810,927

(22) Filed: Nov. 13, 2017

(51) Int. Cl. H01L 29/20; H01L 29/78; H01L 29/08; H01L 29/66

(52) U.S. Cl. CPC H01L 29/2003; H01L 29/66856; H01L 29/0891; H01L 29/78

(57) ABSTRACT

An improved passivation structure for GaN field effect transistor comprising at least one dielectric layer formed on a top surface of a GaN field effect transistor and a passivation layer formed on a top surface of the dielectric layer. The GaN field effect transistor has a gate electrode comprising a Schottky contact metal layer, at least one diffusion barrier metal layer and a high conductivity metal layer. The passivation layer is made of a low cure temperature Polybenzoxazole (PBO) which can be cured at a low-temperature. Thereby the intermixing of the Schottky contact metal layer and the the diffusion barrier metal layer are prevented.

### FIELD OF THE INVENTION

The present invention relates to an improved passivation structure for GaN field effect transistor, especially an improved passivation structure with a low cure temperature PBO.

### BACKGROUND OF THE INVENTION

Please refer to FIG. 17, which is a sectional schematic view of an embodiment of a passivation structure for GaN field effect transistor of conventional technology. In FIG. 17, two GaN field effect transistors 9 are formed on a semiconductor substrate 901. The main structure of the two GaN field effect transistors 9 comprises: a buffer layer 903, a channel layer 904, a Schottky barrier layer 905, two source electrodes 906, a drain electrode 907, two gate electrodes 908, and an isolated layer 918. The semiconductor substrate 901 is made of SiC. The buffer layer 903 is formed on the semiconductor substrate 901. The buffer layer 903 is made of GaN. The channel layer 904 is formed on the buffer layer 903. The channel layer 904 is made of GaN. The Schottky barrier layer 905 is formed on the channel layer 904. The Schottky barrier layer 905 is made of AlGaN. The isolated layer 918 is formed on a top surface of the Schottky barrier layer 905. The isolated layer 918 is made of dielectric material. Two gate dielectric vias 919 are etched such that a bottom of each of the two gate dielectric vias 919 is defined by the top surface of the Schottky barrier layer 905. The two gate electrodes 908 are formed on the top surface of the Schottky barrier layer 905 within the two gate dielectric vias 919 respectively. Each of the two gate electrodes 908 comprises a Schottky contact metal layer 909, a diffusion barrier metal layer 910, a high conductivity metal layer 911 and an adhesion metal layer 912. The Schottky contact metal layer 909 is formed on the top surface of the Schottky barrier layer 905, wherein the Schottky contact metal layer 909 and the Schottky barrier layer 905 form a Schottky contact. The Schottky contact metal layer 909 is made of Ni. The diffusion barrier metal layer 910 is formed on the Schottky contact metal layer 909. The diffusion barrier metal layer 910 is made of Pt. The high conductivity metal layer 911 is formed on the diffusion barrier metal layer 910. The high conductivity metal layer 911 is made of Au. The adhesion metal layer 912 is formed on the high conductivity metal layer 911. The adhesion metal layer 912 is made of Ti. A drain dielectric via 920 is etched such that a bottom of the drain dielectric via 920 is defined by the top surface of the Schottky barrier layer 905. The drain electrode 907 is formed on the top surface of the Schottky barrier layer 905 within the drain dielectric via 920 and located between the two gate electrodes 908. The drain electrode 907 and the Schottky barrier layer 905 form an ohmic contact. Two source dielectric vias 921 are etched such that a bottom of each of the two source dielectric vias 921 is defined by the top surface of the Schottky barrier layer 905. The two source electrodes 906 are formed on the top surface of the Schottky barrier layer 905 within the two source dielectric vias 921 respectively such that the one of the two gate electrodes 908 is located between the drain electrode 907 and one of the two source electrodes 906, while the other one of the two gate electrodes 908 is located between the drain electrode 907 and the other one of the two source electrodes 906. Each of the two source electrodes 906 and the Schottky barrier layer 905 form an ohmic contact. The two GaN field effect transistors 9 further comprise two via holes 916 and a backside metal layer 917. Each of the two via holes 916 penetrates the semiconductor substrate 901. The backside metal layer 917 is formed on a bottom surface of the semiconductor substrate 901 and an inner surface of each of the two via holes 916. The passivation structure 913 for GaN field effect transistor of conventional technology comprises a dielectric layer 914 and a high cure temperature Polybenzoxazole (PBO) passivation layer 915. The dielectric layer 914 is formed on a top surface of the two GaN field effect transistors 9 and the top surface of the Schottky barrier layer 905. The high cure temperature Polybenzoxazole passivation layer 915 is formed on a top surface of the dielectric layer 914. The high cure temperature Polybenzoxazole passivation layer 915 is cured at a temperature greater than or equal to 320° C.

However from the phase diagram of the Au—Pt binary alloy, Au and Pt have excellent miscibility at 300° C. (or less). Hence, when curing the high cure temperature Polybenzoxazole passivation layer 915 at 320° C., it results no problem at the interface between the high conductivity metal layer 911 (Au) and the diffusion barrier metal layer 910 (Pt). The integrity of the interface between the high conductivity metal layer 911 (Au) and the diffusion barrier metal layer 910 (Pt) may be preserved; therefore, the cracks and peeling on the interface may be prevented. In contrast, from the phase diagram of the Pt—Ni binary alloy, Pt and Ni have poor miscibility at 300° C. Therefore, when curing the high cure temperature Polybenzoxazole passivation layer 915 at 320° C., it results in the phenomenon of void defects. Please refer to FIG. 18A, which is a SEM image of an embodiment of a gate electrode of a conventional GaN field effect transistor with no passivation structure before bake at 300° C. The conventional GaN field effect transistor has basically the same structure as the GaN field effect transistor 9, except that the conventional GaN field effect transistor does not have a passivation structure. The SEM image shows that there is no void on the bottom of the gate electrode. Please also refer to FIG. 18B, which is a SEM image of an embodiment of a gate electrode of a conventional GaN field effect transistor with no passivation structure after bake at 300° C. for 6 hours. After bake at 300° C. for 6 hours, there results void defects on the bottom of the gate electrode. Hence, after forming the passivation structure 913 on the conventional GaN field effect transistor and then curing the high cure temperature Polybenzoxazole passivation layer 915 at 320° C., it will result in the phenomenon of void defects on the bottom of the gate electrode. The phenomenon of void defects on the bottom of the gate electrode affects the performance of the conventional GaN field effect transistor.

Accordingly, the present invention has developed a new design which may avoid the above mentioned drawbacks, may significantly enhance the performance, reliability and yield of the devices. Therefore, the present invention then has been invented.

### SUMMARY OF THE INVENTION

The main technical problem that the present invention is seeking to solve is to avoid the phenomenon of void defects on the bottom of the gate electrode after curing the high cure temperature Polybenzoxazole and to prevent the performance of the GaN field effect transistor from being affected by the phenomenon of void defects on the bottom of the gate electrode. The result of solving this main technical problem is enabling GaN field effect transistors to pass environmental reliability tests wherein testing for robustness to humid environments is a concern. The solution to the problem as enables GaN transistors to be used in low cost plastic packages instead of hermetic packages.

In order to solve the problems mentioned the above and to achieve the expected effect, the present invention provides an improved passivation structure for GaN field effect transistor comprising: at least one dielectric layer and a passivation layer. The at least one dielectric layer is formed on a top surface of a GaN field effect transistor, wherein the GaN field effect transistor is formed on a semiconductor substrate, wherein the GaN field effect transistor comprises a wide bandgap epitaxial layer and a gate electrode, wherein the gate electrode comprises a Schottky contact metal layer, at least one diffusion barrier metal layer and a high conductivity metal layer, wherein the wide bandgap epitaxial layer is formed on the semiconductor substrate, wherein the Schottky contact metal layer is formed on the wide bandgap epitaxial layer, wherein the at least one diffusion barrier metal layer is formed on the Schottky contact metal layer, wherein the high conductivity metal layer is formed on the at least one diffusion barrier metal layer. The passivation layer formed on a top surface of the at least one dielectric layer, wherein the passivation layer is made of a low cure temperature Polybenzoxazole (PBO). Thereby the passivation layer is cured at a low-temperature for preventing intermixing of the Schottky contact metal layer and the at least one diffusion barrier metal layer.

In an embodiment of the improved passivation structure for GaN field effect transistor, wherein the passivation layer is cured at greater than or equal to 200° C. and less than or equal to 290° C.

In an embodiment of the improved passivation structure for GaN field effect transistor, wherein the low cure temperature Polybenzoxazole has a dielectric constant greater than or equal to 2 and less than or equal to 4.

In an embodiment of the improved passivation structure for GaN field effect transistor, wherein each of the at least one dielectric layer is made of at least one material selected from the group consisting of: AlOx, aluminium nitride, SiOy and silicon nitride, wherein the x is greater than or equal to 1 and less than or equal to 1.5, wherein the y is greater than or equal to 1 and less than or equal to 2.

In an embodiment of the improved passivation structure for GaN field effect transistor, wherein the Schottky contact metal layer is made of Ni.

In an embodiment of the improved passivation structure for GaN field effect transistor, wherein each of the at least one diffusion barrier metal layer is made of at least one material selected from the group consisting of: Pt, Pd, Ta, W, TiW and Mo.

In an embodiment of the improved passivation structure for GaN field effect transistor, wherein the high conductivity metal layer is made of at least one material selected from the group consisting of: Au, Al, and Cu.

In an embodiment of the improved passivation structure for GaN field effect transistor, wherein the gate electrode further comprises an adhesion metal layer, wherein the adhesion metal layer is formed on the high conductivity metal layer.

In an embodiment of the improved passivation structure for GaN field effect transistor, wherein the adhesion metal layer is made of at least one material selected from the group consisting of: Ti, TiW and TiN.

In an embodiment of the improved passivation structure for GaN field effect transistor, wherein the semiconductor substrate is made of one material selected from the group consisting of: Si, SiC, Diamond, Sapphire and GaN.

In an embodiment of the improved passivation structure for GaN field effect transistor, wherein each of the at least one dielectric layer has a thickness greater than or equal to 10 Å and less than or equal to 8000 Å.

In an embodiment of the improved passivation structure for GaN field effect transistor, wherein the passivation layer has a thickness greater than or equal to 1 μm and less than or equal to 10 μm.

In an embodiment of the improved passivation structure for GaN field effect transistor, wherein the wide bandgap epitaxial layer comprises a channel layer and a Schottky barrier layer, wherein the channel layer is formed on the semiconductor substrate, wherein the Schottky barrier layer is formed on the channel layer, wherein the Schottky contact metal layer is formed on the Schottky barrier layer.

In an embodiment of the improved passivation structure for GaN field effect transistor, wherein the channel layer is made of GaN.

In an embodiment of the improved passivation structure for GaN field effect transistor, wherein the Schottky barrier layer is made of at least one material selected from the group consisting of: AlGaN and GaN.

In an embodiment of the improved passivation structure for GaN field effect transistor, wherein the Schottky barrier layer is made of at least one material selected from the group consisting of: AlGaN, GaN, InAlN and AlN.

In an embodiment of the improved passivation structure for GaN field effect transistor, wherein the wide bandgap epitaxial layer further comprises a cap layer, wherein the cap layer is formed on the Schottky barrier layer, the Schottky contact metal layer is formed on the cap layer.

In an embodiment of the improved passivation structure for GaN field effect transistor, wherein the cap layer is made of at least one material selected from the group consisting of: GaN, AlGaN and AlN.

In an embodiment of the improved passivation structure for GaN field effect transistor, wherein the wide bandgap epitaxial layer further comprises a buffer layer, wherein the buffer layer is formed on the semiconductor substrate, the channel layer is formed on the buffer layer.

In an embodiment of the improved passivation structure for GaN field effect transistor, wherein the buffer layer is made of GaN.

In an embodiment of the improved passivation structure for GaN field effect transistor, wherein the wide bandgap epitaxial layer further comprises a cap layer, wherein the cap layer is formed on the Schottky barrier layer, the Schottky contact metal layer is formed on the cap layer.

In an embodiment of the improved passivation structure for GaN field effect transistor, wherein the cap layer is made of at least one material selected from the group consisting of: GaN, AlGaN and AlN.

In an embodiment of the improved passivation structure for GaN field effect transistor, wherein one of the at least one dielectric layer is made of silicon nitride with a thickness greater than or equal to 10 Å and less than or equal to 8000 Å.

For further understanding the characteristics and effects of the present invention, some preferred embodiments referred to drawings are in detail described as follows.

### BRIEF DESCRIPTION OF DRAWINGS

FIG. 1 is a sectional schematic view of an embodiment of an improved passivation structure for GaN field effect transistor of the present invention.

FIG. 2 is a sectional schematic view of another embodiment of an improved passivation structure for GaN field effect transistor of the present invention.

FIG. 3 is a sectional schematic view of one embodiment of an improved passivation structure for GaN field effect transistor of the present invention.

FIG. 4 is a sectional schematic view of an embodiment of an improved passivation structure for GaN field effect transistor of the present invention.

FIG. 5 is a sectional schematic view of another embodiment of an improved passivation structure for GaN field effect transistor of the present invention.

FIG. 6 is a sectional schematic view of one embodiment of an improved passivation structure for GaN field effect transistor of the present invention.

FIG. 7 is a sectional schematic view of an embodiment of an improved passivation structure for GaN field effect transistor of the present invention.

FIG. 8 is a sectional schematic view of another embodiment of an improved passivation structure for GaN field effect transistor of the present invention.

FIG. 9 is a sectional schematic view of one embodiment of an improved passivation structure for GaN field effect transistor of the present invention.

FIG. 10 is a sectional schematic view of an embodiment of an improved passivation structure for GaN field effect transistor of the present invention.

FIG. 11 is a sectional schematic view of another embodiment of an improved passivation structure for GaN field effect transistor of the present invention.

FIG. 12 is a sectional schematic view of one embodiment of an improved passivation structure for GaN field effect transistor of the present invention.

FIG. 13A is a sectional schematic view of one embodiment of another improved passivation structure for GaN field effect transistor of the present invention.

FIG. 13B is a sectional schematic view of another embodiment of another improved passivation structure for GaN field effect transistor of the present invention.

FIG. 14 is a diagram showing the comparison of the turn on voltage (Von) of the forward diode of the transistor of an embodiment of an improved passivation structure for GaN field effect transistor of the present invention before and after curing the low cure temperature Polybenzoxazole passivation layer and the turn on voltage (Von) of an embodiment of a passivation structure for GaN field effect transistor of conventional technology before and after curing the high cure temperature Polybenzoxazole passivation layer.

FIG. 15 is a diagram showing the comparison of the drain leakage current of an embodiment of an improved passivation structure for GaN field effect transistor of the present invention before and after curing the low cure temperature Polybenzoxazole passivation layer and the drain leakage current of an embodiment of a passivation structure for GaN field effect transistor of conventional technology before and after curing the high cure temperature Polybenzoxazole passivation layer.

FIG. 16 is a diagram showing the comparison of the gate leakage current of an embodiment of an improved passivation structure for GaN field effect transistor of the present invention before and after curing the low cure temperature Polybenzoxazole passivation layer and the gate leakage current of an embodiment of a passivation structure for GaN field effect transistor of conventional technology before and after curing the high cure temperature Polybenzoxazole passivation layer.

FIG. 17 is a sectional schematic view of an embodiment of a passivation structure for GaN field effect transistor of conventional technology.

FIG. 18A is a SEM image of an embodiment of a gate electrode of a conventional GaN field effect transistor with no passivation structure before bake at 300° C.

FIG. 18B is a SEM image of an embodiment of a gate electrode of a conventional GaN field effect transistor with no passivation structure after bake at 300° C. for 6 hours.

### DETAILED DESCRIPTIONS OF PREFERRED EMBODIMENTS

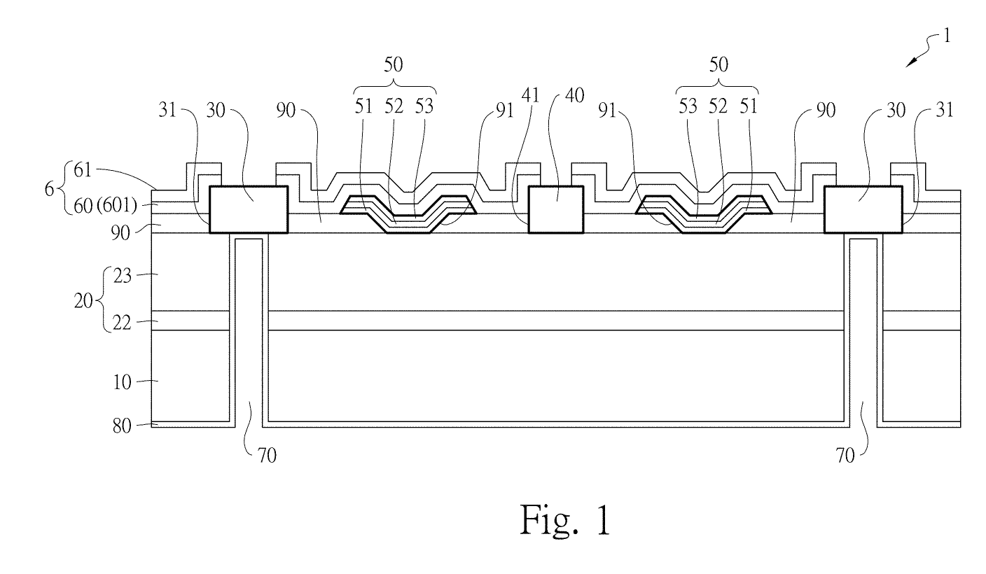

Please refer to FIG. 1, which is a sectional schematic view of an embodiment of an improved passivation structure for GaN field effect transistor of the present invention. In the embodiment of FIG. 1, two GaN field effect transistors 1 are formed on a semiconductor substrate 10. The main structure of the two GaN field effect transistors 1 comprises: a wide bandgap epitaxial layer 20, two source electrodes 30, a drain electrode 40, two gate electrodes 50 and an isolated layer 90. The wide bandgap epitaxial layer 20 is formed on the semiconductor substrate 10. The semiconductor substrate 10 is made of one material selected from the group consisting of: Si, SiC, Diamond, Sapphire and GaN. The wide bandgap epitaxial layer 20 comprises a channel layer 22 and a Schottky barrier layer 23. The channel layer 22 is formed on the semiconductor substrate 10. The Schottky barrier layer 23 is formed on the channel layer 22. The channel layer 22 is made of GaN. The Schottky barrier layer 23 is made of at least one material selected from the group consisting of: AlGaN and GaN. The isolated layer 90 is formed on a top surface of the wide bandgap epitaxial layer 20. The isolated layer 90 is made of dielectric material. Two gate dielectric vias 91 are etched such that a bottom of each of the two gate dielectric vias 91 is defined by the top surface of the wide bandgap epitaxial layer 20. The two gate electrodes 50 are formed on the top surface of the wide bandgap epitaxial layer 20 within the two gate dielectric vias 91 respectively. Each of the two gate electrodes 50 comprises a Schottky contact metal layer 51, at least one diffusion barrier metal layer 52 and a high conductivity metal layer 53. The Schottky contact metal layer 51 is formed on the top surface of the wide bandgap epitaxial layer 20. The at least one diffusion barrier metal layer 52 is formed on the Schottky contact metal layer 51. The high conductivity metal layer 53 is formed on the at least one diffusion barrier metal layer 52. Each of the Schottky contact metal layer 51 of the two gate electrodes 50 and the Schottky barrier layer 23 of the wide bandgap epitaxial layer 20 form a Schottky contact. The Schottky contact metal layer 51 is made of Ni. Each of the at least one diffusion barrier metal layer 52 is made of at least one material selected from the group consisting of: Pt, Pd, Ta, W, TiW and Mo. The high conductivity metal layer 53 is made of at least one material selected from the group consisting of: Au, Al, and Cu. A drain dielectric via 41 is etched such that a bottom of the drain dielectric via 41 is defined by the top surface of the wide bandgap epitaxial layer 20. The drain electrode 40 is formed on the top surface of the wide bandgap epitaxial layer 20 within the drain dielectric via 41 and located between the two gate electrodes 50. The drain electrode 40 and the Schottky barrier layer 23 of the wide bandgap epitaxial layer 20 form an ohmic contact. Two source dielectric vias 31 are etched such that a bottom of each of the two source dielectric vias 31 is defined by the top surface of the wide bandgap epitaxial layer 20. The two source electrodes 30 are formed on the top surface of the wide bandgap epitaxial layer 20 within the two source dielectric vias 31 respectively such that the one of the two gate electrodes 50 is located between the drain electrode 40 and one of the two source electrodes 30, while the other one of the two gate electrodes 50 is located between the drain electrode 40 and the other one of the two source electrodes 30. Each of the two source electrodes 30 and the Schottky barrier layer 23 of the wide bandgap epitaxial layer 20 form an ohmic contact. The two GaN field effect transistors 1 further comprise two via holes 70 and a backside metal layer 80. Each of the two via holes 70 penetrates the semiconductor substrate 10. Each via hole 70 has an inner surface. A top of the inner surface the via hole 70 is defined by the source electrode 30. The backside metal layer 80 is formed on a bottom surface of the semiconductor substrate 10 and the inner surface of each of the two via holes 70 such that the backside metal layer 80 and the two source electrodes 30 are electrically contacted respectively at the top of the inner surface of each of the two via holes 70. The improved passivation structure 6 for GaN field effect transistor 1 of the present invention comprises at least one dielectric layer 60 and a passivation layer 61. The at least one dielectric layer 60 is formed on a top surface of the GaN field effect transistors 1 and the top surface of the wide bandgap epitaxial layer 20. The passivation layer 61 is formed on a top surface of the at least one dielectric layer 60. In current embodiment, the at least one dielectric layer 60 comprises a dielectric layer 601. The dielectric layer 601 is made of at least one material selected from the group consisting of: AlOx, aluminium nitride, SiOy and silicon nitride, wherein the x is greater than or equal to 1 and less than or equal to 1.5, wherein the y is greater than or equal to 1 and less than or equal to 2. The dielectric layer 601 has a thickness greater than or equal to 10 Å and less than or equal to 8000 Å. The passivation layer 61 is made of a low cure temperature Polybenzoxazole (PBO), thereby the passivation layer 61 is cured at a low-temperature for preventing intermixing of the Schottky contact metal layer 51 and the at least one diffusion barrier metal layer 52. The passivation layer 61 is cured at greater than or equal to 200° C. and less than or equal to 290° C. The low cure temperature Polybenzoxazole has a dielectric constant greater than or equal to 2 and less than or equal to 4. The passivation layer 61 has a thickness greater than or equal to 1 μm and less than or equal to 10 μm.

In some embodiments, the Schottky barrier layer 23 is made of at least one material selected from the group consisting of: AlGaN, GaN, InAlN and AlN.

In some embodiments, one of the at least one dielectric layer 60 is made of silicon nitride with a thickness greater than or equal to 10 Å and less than or equal to 8000 Å.

In some embodiments, the passivation layer 61 is cured at greater than or equal to 200° C. and less than or equal to 285° C., greater than or equal to 200° C. and less than or equal to 280° C., greater than or equal to 200° C. and less than or equal to 275° C., greater than or equal to 200° C. and less than or equal to 270° C., greater than or equal to 200° C. and less than or equal to 265° C., greater than or equal to 205° C. and less than or equal to 290° C., greater than or equal to 210° C. and less than or equal to 290° C., greater than or equal to 215° C. and less than or equal to 290° C., greater than or equal to 220° C. and less than or equal to 290° C., or greater than or equal to 225° C. and less than or equal to 290° C.

In some embodiments, the low cure temperature Polybenzoxazole has a dielectric constant greater than or equal to 2 and less than or equal to 3.8, greater than or equal to 2 and less than or equal to 3.6, greater than or equal to 2 and less than or equal to 3.4, greater than or equal to 2 and less than or equal to 3.2, greater than or equal to 2 and less than or equal to 3.1, greater than or equal to 2.2 and less than or equal to 4, greater than or equal to 2.4 and less than or equal to 4, greater than or equal to 2.6 and less than or equal to 4, greater than or equal to 2.8 and less than or equal to 4, or greater than or equal to 2.9 and less than or equal to 4.

In some embodiments, the dielectric layer 601 has a thickness greater than or equal to 10 Å and less than or equal to 7500 Å, greater than or equal to 10 Å and less than or equal to 7000 Å, greater than or equal to 10 Å and less than or equal to 6500 Å, greater than or equal to 10 Å and less than or equal to 6000 Å, greater than or equal to 10 Å and less than or equal to 5500 Å, greater than or equal to 10 Å and less than or equal to 5000 Å, greater than or equal to 30 Å and less than or equal to 8000 Å, greater than or equal to 50 Å and less than or equal to 8000 Å, greater than or equal to 80 Å and less than or equal to 8000 Å, greater than or equal to 100 Å and less than or equal to 8000 Å, greater than or equal to 200 Å and less than or equal to 8000 Å, greater than or equal to 300 Å and less than or equal to 8000 Å, greater than or equal to 400 Å and less than or equal to 8000 Å, greater than or equal to 500 Å and less than or equal to 8000 Å, or greater than or equal to 700 Å and less than or equal to 8000 Å.

In some embodiments, the passivation layer 61 has a thickness greater than or equal to 1 μm and less than or equal to 9.5 μm, greater than or equal to 1 μm and less than or equal to 9 μm, greater than or equal to 1 μm and less than or equal to 8.5 μm, greater than or equal to 1 μm and less than or equal to 8 μm, greater than or equal to 1 μm and less than or equal to 7.5 μm, greater than or equal to 1 μm and less than or equal to 7 μm, greater than or equal to 1.5 μm and less than or equal to 10 μm, greater than or equal to 2 μm and less than or equal to 10 μm, greater than or equal to 2.5 μm and less than or equal to 10 μm, greater than or equal to 3 μm and less than or equal to 10 μm, greater than or equal to 3.5 μm and less than or equal to 10 μm, or greater than or equal to 4 μm and less than or equal to 10 μm.

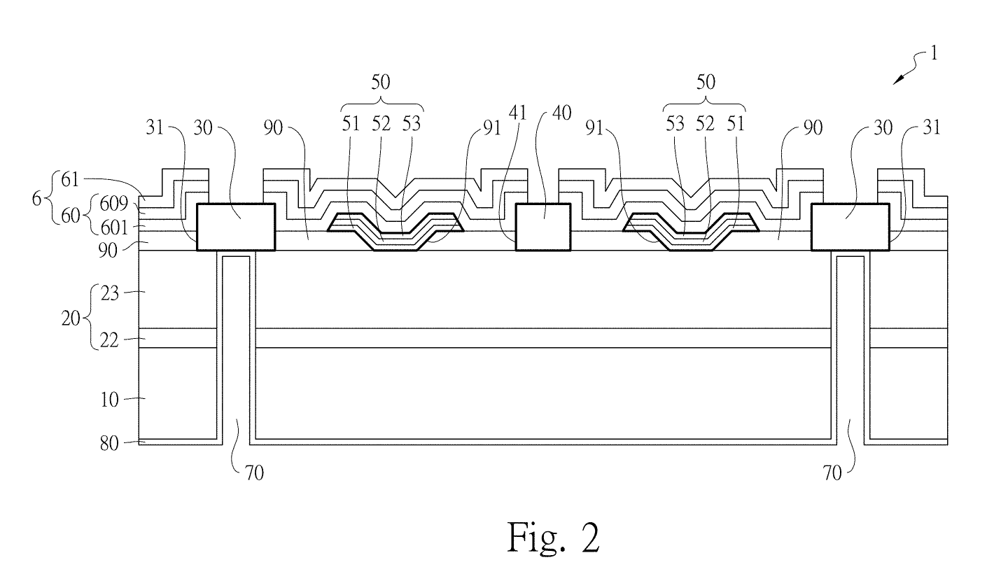

Please refer to FIG. 2, which is a sectional schematic view of another embodiment of an improved passivation structure for GaN field effect transistor of the present invention. The main structure of the embodiment of FIG. 2 is basically the same as the structure of the embodiment of FIG. 1, except that the at least one dielectric layer 60 further comprises a dielectric layer 609. The dielectric layer 609 is formed on the dielectric layer 601. The passivation layer 61 is formed on the dielectric layer 609. The dielectric layer 609 is made of at least one material selected from the group consisting of: AlOx, aluminium nitride, SiOy and silicon nitride, wherein the x is greater than or equal to 1 and less than or equal to 1.5, wherein the y is greater than or equal to 1 and less than or equal to 2. The dielectric layer 609 has a thickness greater than or equal to 10 Å and less than or equal to 8000 Å.

In some embodiments, the dielectric layer 609 has a thickness greater than or equal to 10 Å and less than or equal to 7500 Å, greater than or equal to 10 Å and less than or equal to 7000 Å, greater than or equal to 10 Å and less than or equal to 6500 Å, greater than or equal to 10 Å and less than or equal to 6000 Å, greater than or equal to 10 Å and less than or equal to 5500 Å, greater than or equal to 10 Å and less than or equal to 5000 Å, greater than or equal to 30 Å and less than or equal to 8000 Å, greater than or equal to 50 Å and less than or equal to 8000 Å, greater than or equal to 80 Å and less than or equal to 8000 Å, greater than or equal to 100 Å and less than or equal to 8000 Å, greater than or equal to 200 Å and less than or equal to 8000 Å, greater than or equal to 300 Å and less than or equal to 8000 Å, greater than or equal to 400 Å and less than or equal to 8000 Å, greater than or equal to 500 Å and less than or equal to 8000 Å, or greater than or equal to 700 Å and less than or equal to 8000 Å.

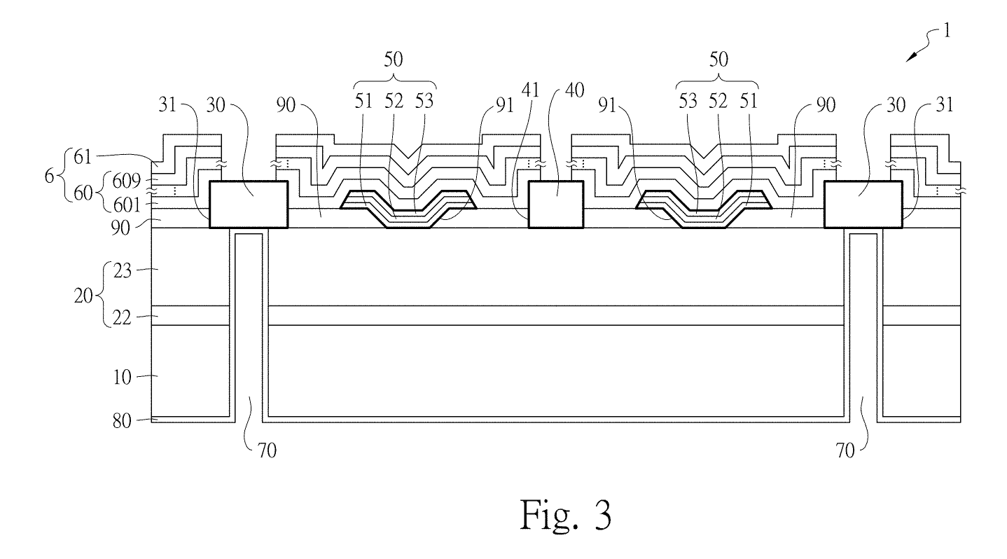

Please refer to FIG. 3, which is a sectional schematic view of one embodiment of an improved passivation structure for GaN field effect transistor of the present invention. The main structure of the embodiment of FIG. 3 is basically the same as the structure of the embodiment of FIG. 2, except that the at least one dielectric layer 60 further comprises one or more dielectric layer(s) between the dielectric layer 601 and the dielectric layer 609. Each of the one or more dielectric layer(s) is made of at least one material selected from the group consisting of: AlOx, aluminium nitride, SiOy and silicon nitride, wherein the x is greater than or equal to 1 and less than or equal to 1.5, wherein the y is greater than or equal to 1 and less than or equal to 2. Each of the one or more dielectric layer(s) has a thickness greater than or equal to 10 Å and less than or equal to 8000 Å. In some embodiments, each a Schottky contact metal layer, at least one diffusion barrier metal layer and a high conductivity metal layer has a thickness greater than or equal to 10 Å and less than or equal to 7500 Å, greater than or equal to 10 Å and less than or equal to 7000 Å, greater than or equal to 10 Å and less than or equal to 6500 Å, greater than or equal to 10 Å and less than or equal to 6000 Å, greater than or equal to 10 Å and less than or equal to 5500 Å, greater than or equal to 10 Å and less than or equal to 5000 Å, greater than or equal to 30 Å and less than or equal to 8000 Å, greater than or equal to 50 Å and less than or equal to 8000 Å, greater than or equal to 80 Å and less than or equal to 8000 Å, greater than or equal to 100 Å and less than or equal to 8000 Å, greater than or equal to 200 Å and less than or equal to 8000 Å, greater than or equal to 300 Å and less than or equal to 8000 Å, greater than or equal to 400 Å and less than or equal to 8000 Å, greater than or equal to 500 Å and less than or equal to 8000 Å, or greater than or equal to 700 Å and less than or equal to 8000 Å.

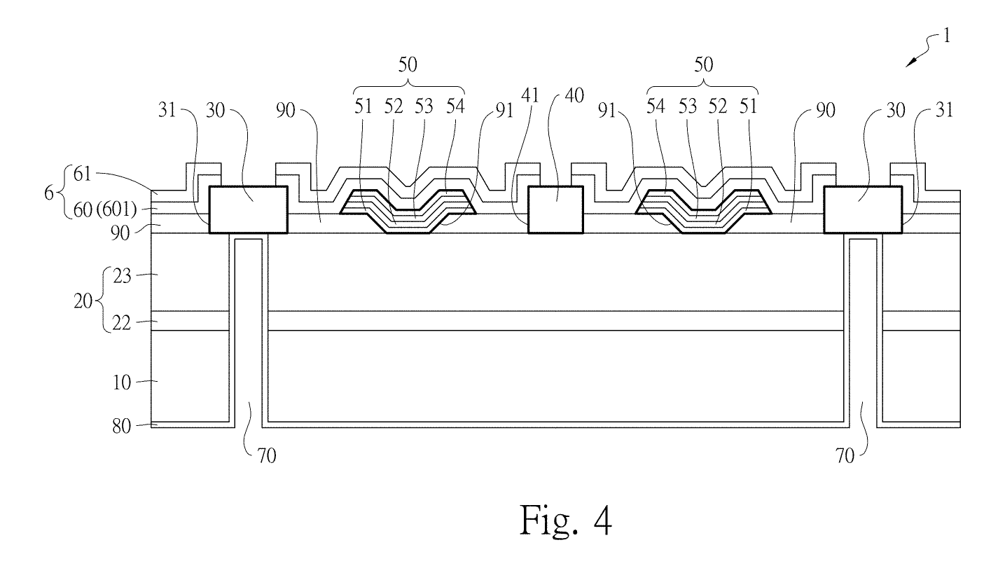

Please refer to FIG. 4, which is a sectional schematic view of an embodiment of an improved passivation structure for GaN field effect transistor of the present invention. The main structure of the embodiment of FIG. 4 is basically the same as the structure of the embodiment of FIG. 1, except that each of the two gate electrodes 50 further comprises an adhesion metal layer 54. The adhesion metal layer 54 is formed on the high conductivity metal layer 53. The The adhesion metal layer 54 is made of at least one material selected from the group consisting of: Ti, TiW and TiN.

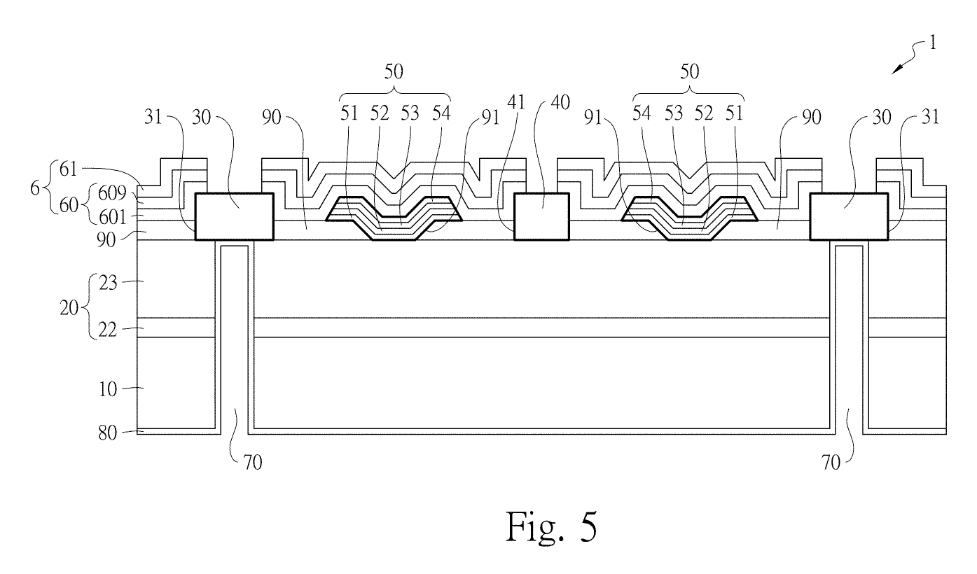

Please refer to FIG. 5, which is a sectional schematic view of another embodiment of an improved passivation structure for GaN field effect transistor of the present invention. The main structure of the embodiment of FIG. 5 is basically the same as the structure of the embodiment of FIG. 2, except that each of the two gate electrodes 50 further comprises an adhesion metal layer 54. The adhesion metal layer 54 is formed on the high conductivity metal layer 53. The The adhesion metal layer 54 is made of at least one material selected from the group consisting of: Ti, TiW and TiN.

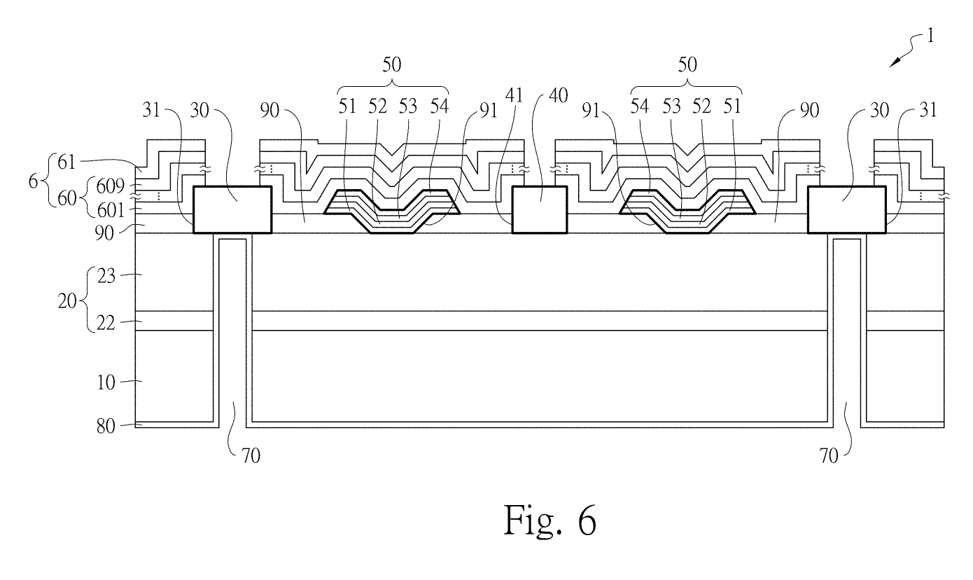

Please refer to FIG. 6, which is a sectional schematic view of one embodiment of an improved passivation structure for GaN field effect transistor of the present invention. The main structure of the embodiment of FIG. 6 is basically the same as the structure of the embodiment of FIG. 3, except that each of the two gate electrodes 50 further comprises an adhesion metal layer 54. The adhesion metal layer 54 is formed on the high conductivity metal layer 53. The The adhesion metal layer 54 is made of at least one material selected from the group consisting of: Ti, TiW and TiN.

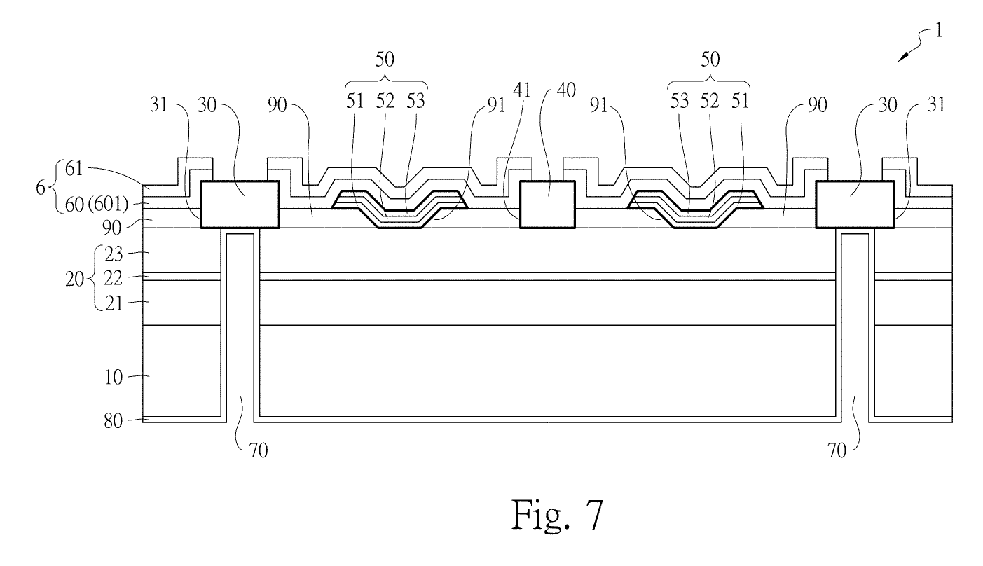

Please refer to FIG. 7, which is a sectional schematic view of an embodiment of an improved passivation structure for GaN field effect transistor of the present invention. The main structure of the embodiment of FIG. 7 is basically the same as the structure of the embodiment of FIG. 1, except that the wide bandgap epitaxial layer 20 further comprises a buffer layer 21. The buffer layer 21 is formed on the semiconductor substrate 10. The channel layer 22 is formed on the buffer layer 21. The buffer layer 21 is made of GaN.

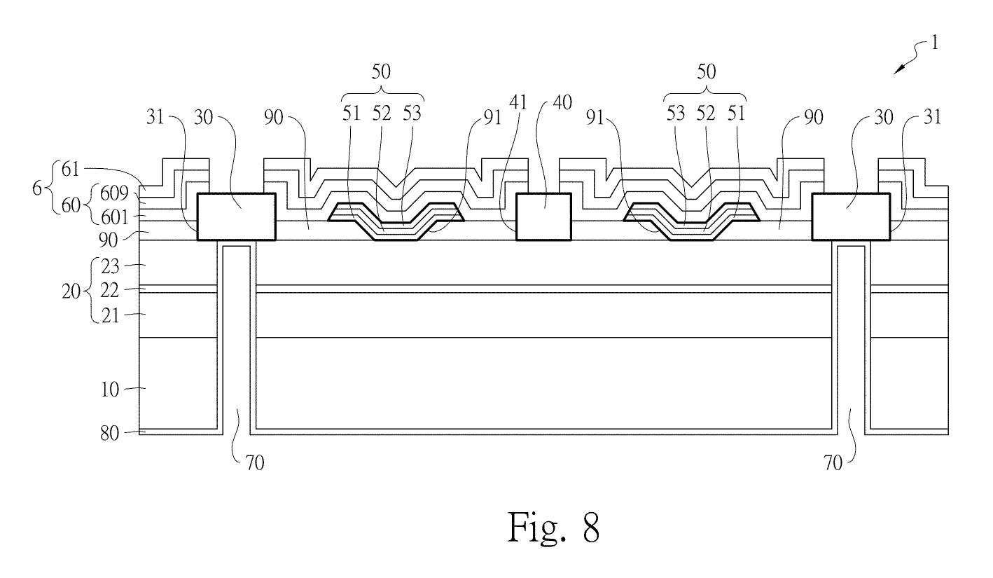

Please refer to FIG. 8, which is a sectional schematic view of another embodiment of an improved passivation structure for GaN field effect transistor of the present invention. The main structure of the embodiment of FIG. 8 is basically the same as the structure of the embodiment of FIG. 2, except that the wide bandgap epitaxial layer 20 further comprises a buffer layer 21. The buffer layer 21 is formed on the semiconductor substrate 10. The channel layer 22 is formed on the buffer layer 21. The buffer layer 21 is made of GaN.

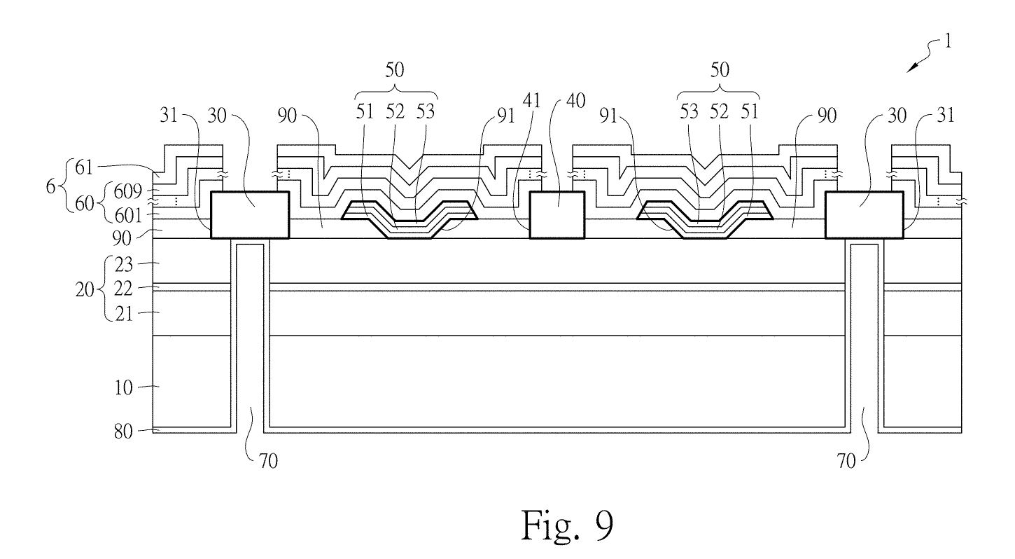

Please refer to FIG. 9, which is a sectional schematic view of one embodiment of an improved passivation structure for GaN field effect transistor of the present invention. The main structure of the embodiment of FIG. 9 is basically the same as the structure of the embodiment of FIG. 3, except that the wide bandgap epitaxial layer 20 further comprises a buffer layer 21. The buffer layer 21 is formed on the semiconductor substrate 10. The channel layer 22 is formed on the buffer layer 21. The buffer layer 21 is made of GaN.

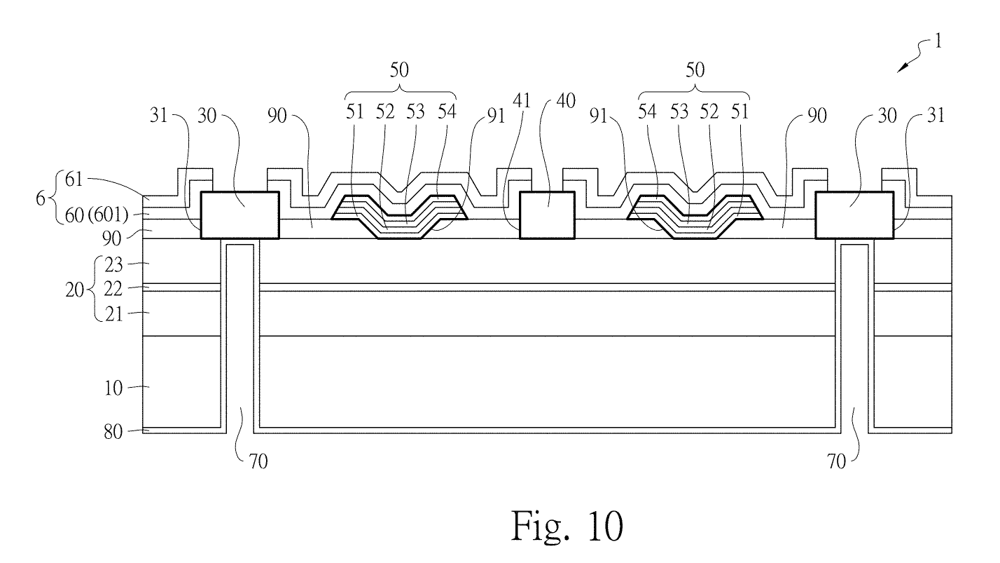

Please refer to FIG. 10, which is a sectional schematic view of an embodiment of an improved passivation structure for GaN field effect transistor of the present invention. The main structure of the embodiment of FIG. 10 is basically the same as the structure of the embodiment of FIG. 4, except that the wide bandgap epitaxial layer 20 further comprises a buffer layer 21. The buffer layer 21 is formed on the semiconductor substrate 10. The channel layer 22 is formed on the buffer layer 21. The buffer layer 21 is made of GaN.

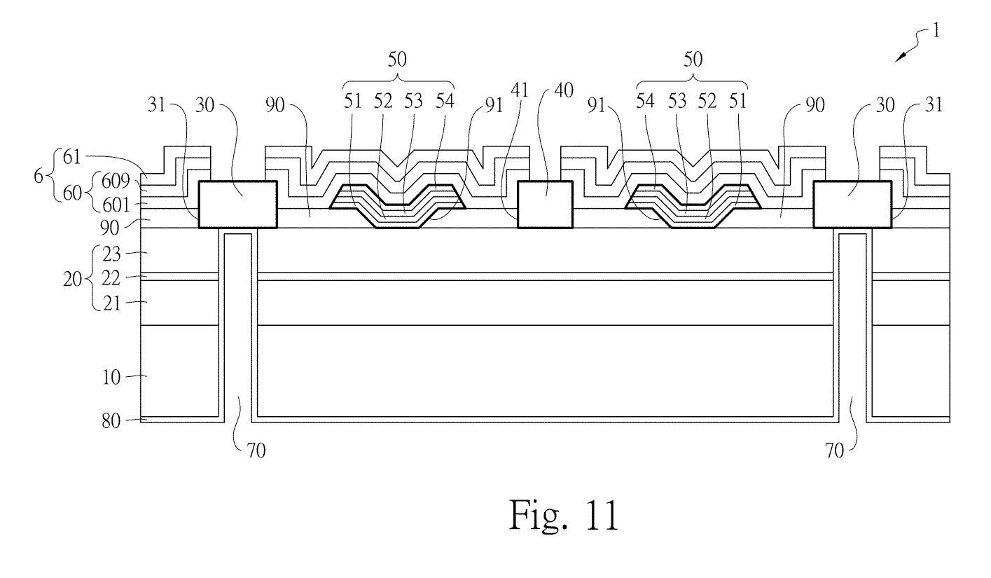

Please refer to FIG. 11, which is a sectional schematic view of another embodiment of an improved passivation structure for GaN field effect transistor of the present invention. The main structure of the embodiment of FIG. 11 is basically the same as the structure of the embodiment of FIG. 5, except that the wide bandgap epitaxial layer 20 further comprises a buffer layer 21. The buffer layer 21 is formed on the semiconductor substrate 10. The channel layer 22 is formed on the buffer layer 21. The buffer layer 21 is made of GaN.

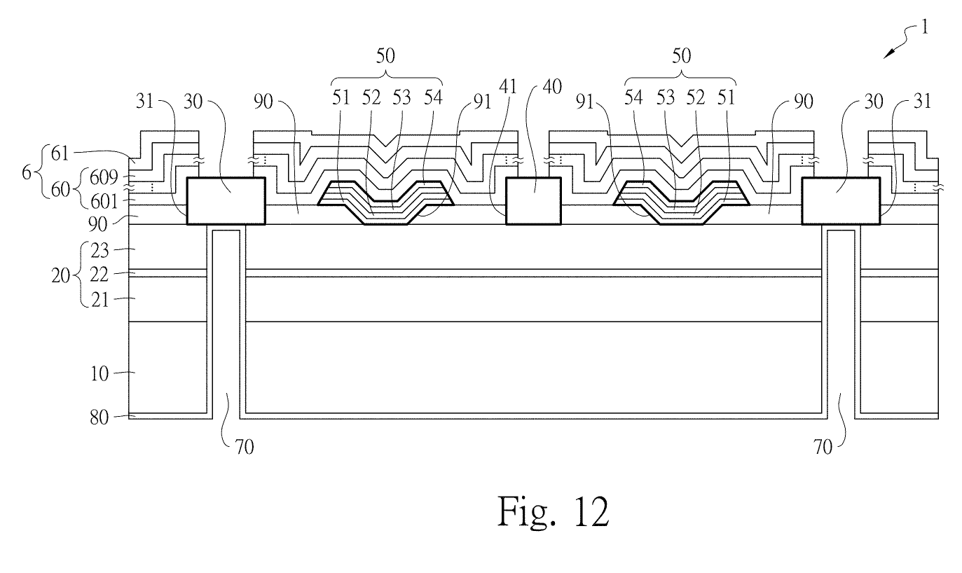

Please refer to FIG. 12, which is a sectional schematic view of one embodiment of an improved passivation structure for GaN field effect transistor of the present invention. The main structure of the embodiment of FIG. 12 is basically the same as the structure of the embodiment of FIG. 6, except that the wide bandgap epitaxial layer 20 further comprises a buffer layer 21. The buffer layer 21 is formed on the semiconductor substrate 10. The channel layer 22 is formed on the buffer layer 21. The buffer layer 21 is made of GaN.

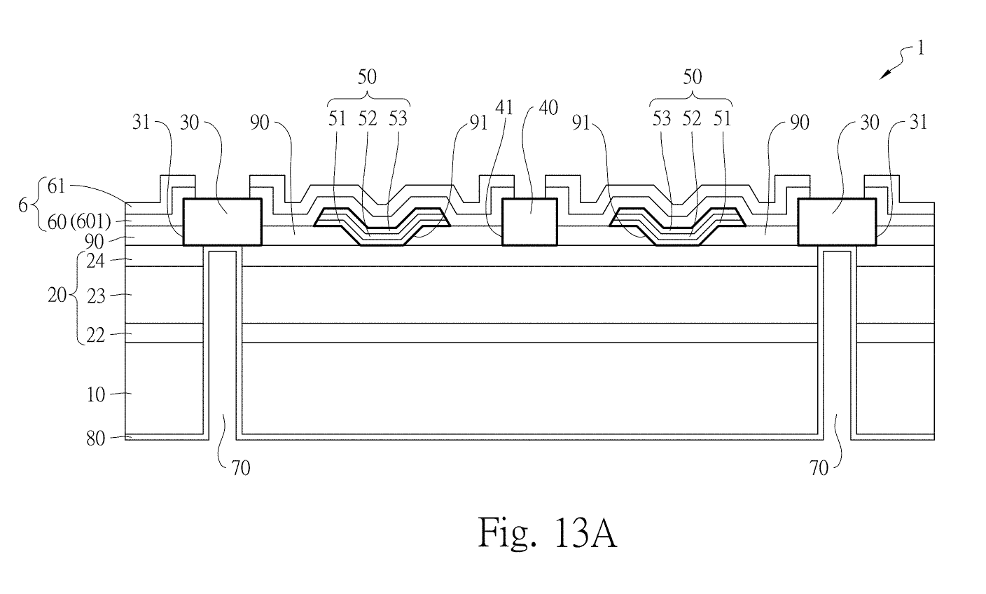

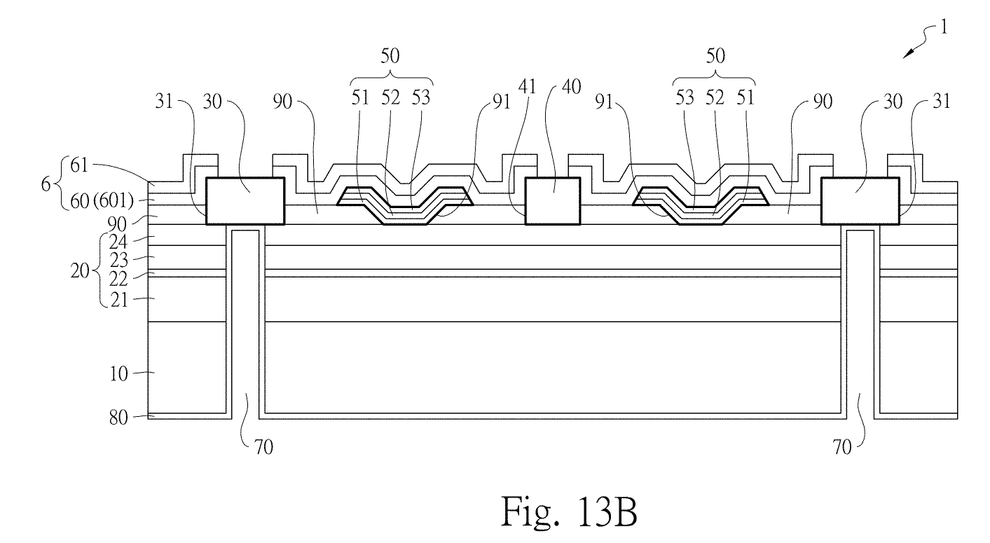

Please refer to FIG. 13A, which is a sectional schematic view of one embodiment of another improved passivation structure for GaN field effect transistor of the present invention. The main structure of the embodiment of FIG. 13A is basically the same as the structure of the embodiment of FIG. 1, except that the wide bandgap epitaxial layer 20 further comprises a cap layer 24, wherein the cap layer 24 is formed on the Schottky barrier layer 23, wherein the isolated layer 90 is formed on the Schottky barrier layer 23; wherein the two gate electrodes 50 are formed on the top surface (the cap layer 24) of the wide bandgap epitaxial layer 20 within the two gate dielectric vias 91 respectively, wherein each of the Schottky contact metal layer 51 of the two gate electrodes 50 and the cap layer 24 of the wide bandgap epitaxial layer 20 form a Schottky contact; wherein the drain electrode 40 is formed on the top surface (the cap layer 24) of the wide bandgap epitaxial layer 20 within the drain dielectric via 41 and located between the two gate electrodes 50, wherein the drain electrode 40 and the cap layer 24 of the wide bandgap epitaxial layer 20 form an ohmic contact; wherein each of the two source electrodes 30 and the cap layer 24 of the wide bandgap epitaxial layer 20 form an ohmic contact. The cap layer 24 is made of at least one material selected from the group consisting of: GaN, AlGaN and AlN. Please refer to FIG. 13B, which is a sectional schematic view of one embodiment of another improved passivation structure for GaN field effect transistor of the present invention. The main structure of the embodiment of FIG. 13B is basically the same as the structure of the embodiment of FIG. 7, except that the wide bandgap epitaxial layer 20 further comprises a cap layer 24, wherein the cap layer 24 is formed on the Schottky barrier layer 23, wherein the isolated layer 90 is formed on the Schottky barrier layer 23; wherein the two gate electrodes 50 are formed on the top surface (the cap layer 24) of the wide bandgap epitaxial layer 20 within the two gate dielectric vias 91 respectively, wherein each of the Schottky contact metal layer 51 of the two gate electrodes 50 and the cap layer 24 of the wide bandgap epitaxial layer 20 form a Schottky contact; wherein the drain electrode 40 is formed on the top surface (the cap layer 24) of the wide bandgap epitaxial layer 20 within the drain dielectric via 41 and located between the two gate electrodes 50, wherein the drain electrode 40 and the cap layer 24 of the wide bandgap epitaxial layer 20 form an ohmic contact; wherein each of the two source electrodes 30 and the cap layer 24 of the wide bandgap epitaxial layer 20 form an ohmic contact. The cap layer 24 is made of at least one material selected from the group consisting of: GaN, AlGaN and AlN. Similarly, in the embodiments of FIGS. 2, 3, 4, 5, 6, 8. 9. 10. 11 and 12 of the present invention, the wide bandgap epitaxial layer 20 may further comprises a cap layer 24 (not shown in Figure), wherein the cap layer 24 is formed on the Schottky barrier layer 23, wherein the isolated layer 90 is formed on the Schottky barrier layer 23; wherein the two gate electrodes 50 are formed on the top surface (the cap layer 24) of the wide bandgap epitaxial layer 20 within the two gate dielectric vias 91 respectively, wherein each of the Schottky contact metal layer 51 of the two gate electrodes 50 and the cap layer 24 of the wide bandgap epitaxial layer 20 form a Schottky contact; wherein the drain electrode 40 is formed on the top surface (the cap layer 24) of the wide bandgap epitaxial layer 20 within the drain dielectric via 41 and located between the two gate electrodes 50, wherein the drain electrode 40 and the cap layer 24 of the wide bandgap epitaxial layer 20 form an ohmic contact; wherein each of the two source electrodes 30 and the cap layer 24 of the wide bandgap epitaxial layer 20 form an ohmic contact. The cap layer 24 is made of at least one material selected from the group consisting of: GaN, AlGaN and AlN.

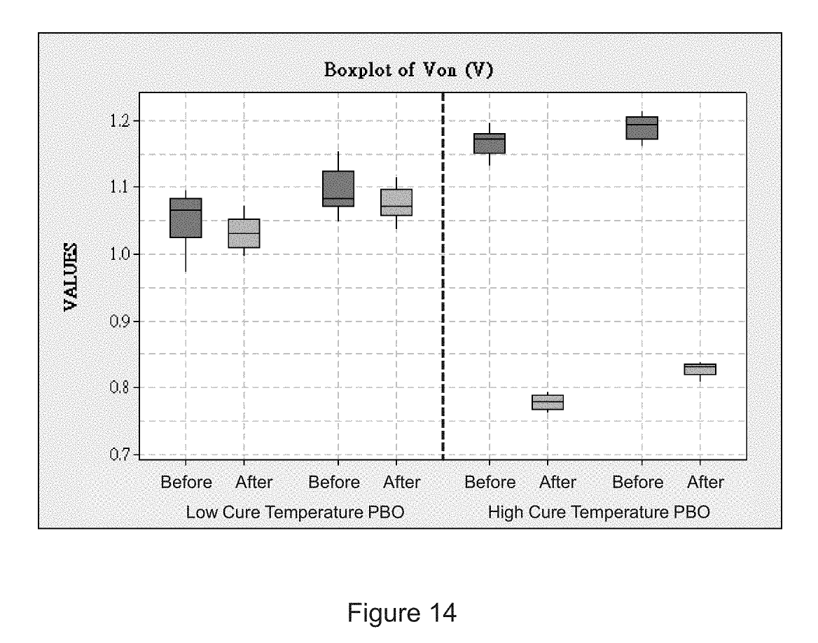

Please refer to FIG. 14, which is a diagram showing the comparison of the turn on voltage (Von) of the forward diode of the transistor of an embodiment of an improved passivation structure for GaN field effect transistor of the present invention before and after curing the low cure temperature Polybenzoxazole passivation layer and the turn on voltage (Von) of an embodiment of a passivation structure for GaN field effect transistor of conventional technology before and after curing the high cure temperature Polybenzoxazole passivation layer. The right-hand side are the turn on voltage (Von) of two batches of samples of a passivation structure for GaN field effect transistor of conventional technology before and after curing the high cure temperature Polybenzoxazole passivation layer. The left-hand side are the turn on voltage (Von) of two batches of samples of an improved passivation structure for GaN field effect transistor of the present invention before and after curing the low cure temperature Polybenzoxazole passivation layer. It is very clear that the turn on voltage (Von) of the GaN field effect transistor of conventional technology decreases dramatically, while the turn on voltage (Von) of an improved passivation structure for GaN field effect transistor of the present invention mostly remains unchanged.

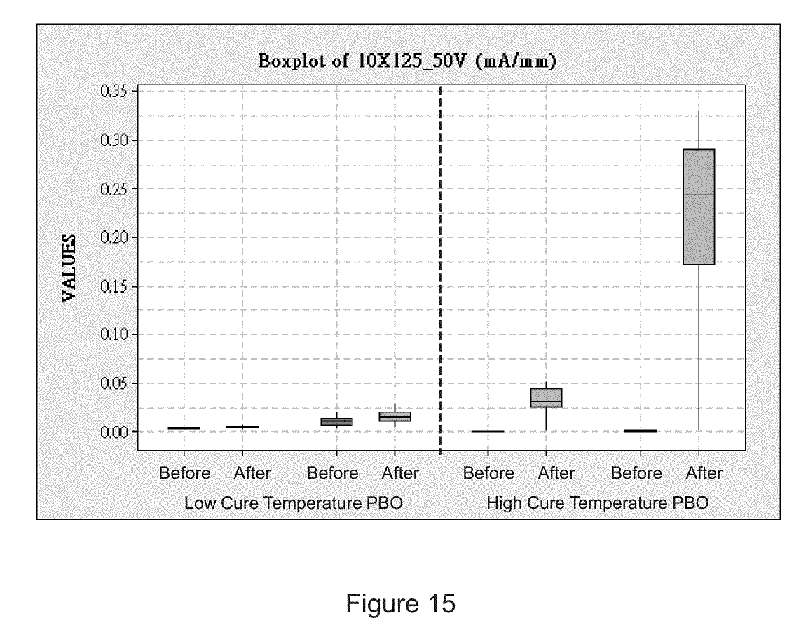

Please also refer to FIG. 15, which is a diagram showing the comparison of the drain leakage current of an embodiment of an improved passivation structure for GaN field effect transistor of the present invention before and after curing the low cure temperature Polybenzoxazole passivation layer and the drain leakage current of an embodiment of a passivation structure for GaN field effect transistor of conventional technology before and after curing the high cure temperature Polybenzoxazole passivation layer. The right-hand side are the drain leakage current of two batches of samples of a passivation structure for GaN field effect transistor of conventional technology before and after curing the high cure temperature Polybenzoxazole passivation layer. The left-hand side are the drain leakage current of two batches of samples of an improved passivation structure for GaN field effect transistor of the present invention before and after curing the low cure temperature Polybenzoxazole passivation layer. It is very clear that the drain leakage current of the GaN field effect transistor of conventional technology increases dramatically, while the drain leakage current of an improved passivation structure for GaN field effect transistor of the present invention mostly remains unchanged.

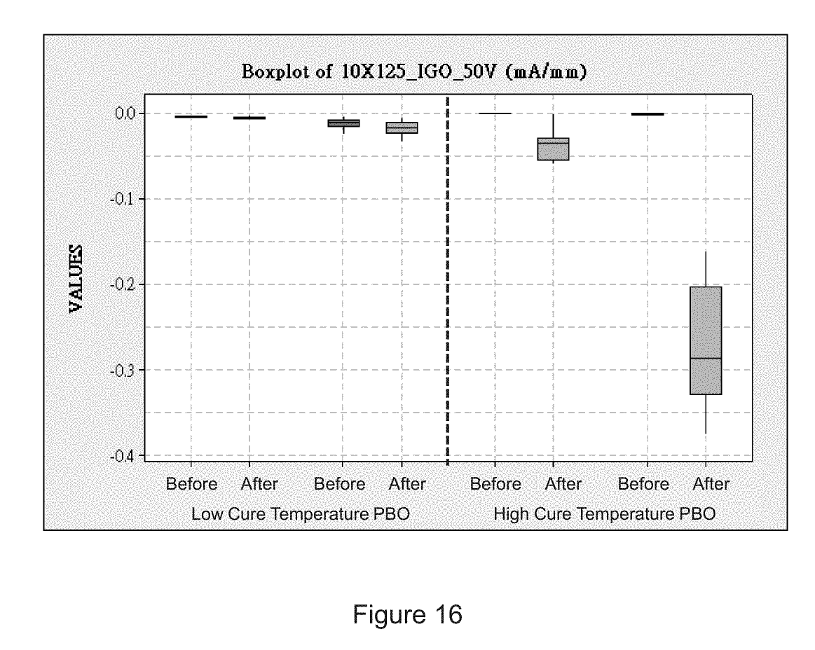

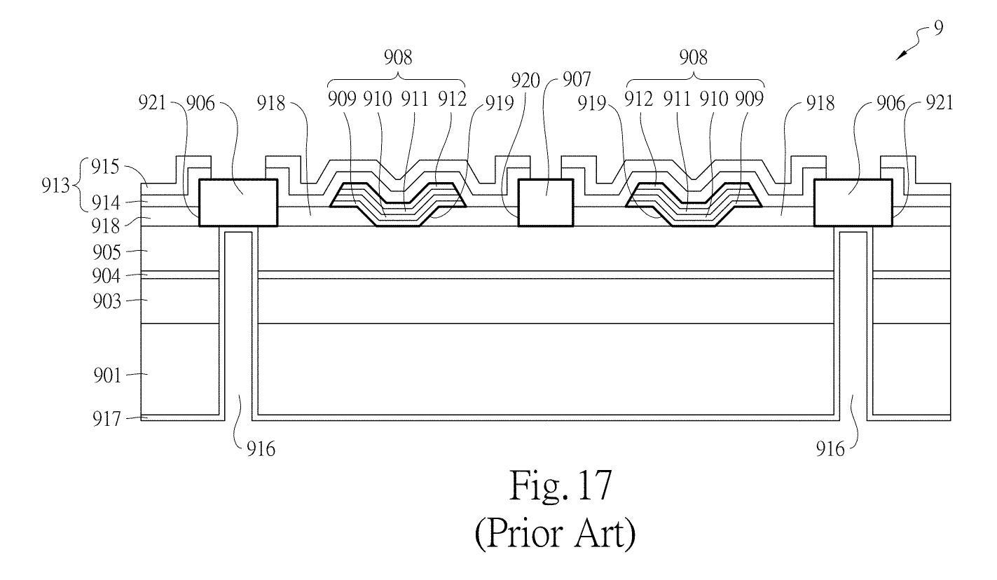

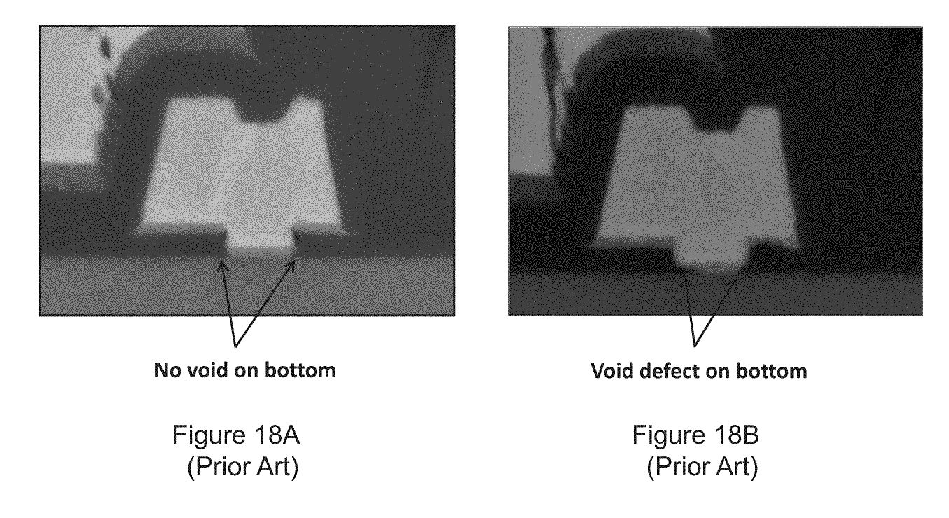

Please also refer to FIG. 16, which is a diagram showing the comparison of the gate leakage current of an embodiment of an improved passivation structure for GaN field effect transistor of the present invention before and after curing the low cure temperature Polybenzoxazole passivation layer and the gate leakage current of an embodiment of a passivation structure for GaN field effect transistor of conventional technology before and after curing the high cure temperature Polybenzoxazole passivation layer. The right-hand side are the gate leakage current of two batches of samples of a passivation structure for GaN field effect transistor of conventional technology before and after curing the high cure temperature Polybenzoxazole passivation layer. The left-hand side are the gate leakage current of two batches of samples of an improved passivation structure for GaN field effect transistor of the present invention before and after curing the low cure temperature Polybenzoxazole passivation layer. It is very clear that the gate leakage current of the GaN field effect transistor of conventional technology gets worse dramatically, while the gate leakage current of an improved passivation structure for GaN field effect transistor of the present invention mostly remains unchanged.

As disclosed in the above description and attached drawings, the present invention can provide an improved passivation structure for GaN field effect transistor. It is new and can be put into industrial use.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

1. An improved passivation structure for GaN field effect transistor comprising:
at least one dielectric layer formed on a top surface of a GaN field effect transistor, wherein said GaN field effect transistor is formed on a semiconductor substrate, wherein said GaN field effect transistor comprises a wide bandgap epitaxial layer and a gate electrode, wherein said gate electrode comprises a Schottky contact metal layer, at least one diffusion barrier metal layer and a high conductivity metal layer, wherein said wide bandgap epitaxial layer is formed on said semiconductor substrate, wherein said Schottky contact metal layer is formed on said wide bandgap epitaxial layer, wherein said at least one diffusion barrier metal layer is formed on said Schottky contact metal layer, wherein said high conductivity metal layer is formed on said at least one diffusion barrier metal layer, wherein each of said at least one diffusion barrier metal layer is made of at least one material selected from the group consisting of: Pd and TiW; and
a passivation layer formed on a top surface of said at least one dielectric layer, wherein said passivation layer is made of a Polybenzoxazole (PBO);
thereby said passivation layer is cured at greater than or equal to 200° C. and less than or equal to 290° C. for preventing intermixing of said Schottky contact metal layer and said at least one diffusion barrier metal layer.

2. (canceled)

3. The improved passivation structure for GaN field effect transistor according to claim 1, wherein said Polybenzoxazole has a dielectric constant greater than or equal to 2 and less than or equal to 4.

4. The improved passivation structure for GaN field effect transistor according to claim 1, wherein each of said at least one dielectric layer is made of at least one material selected from the group consisting of: AlOx, aluminium nitride, SiOy and silicon nitride, wherein said x is greater than or equal to 1 and less than or equal to 1.5, wherein said y is greater than or equal to 1 and less than or equal to 2.

5. The improved passivation structure for GaN field effect transistor according to claim 1, wherein said Schottky contact metal layer is made of Ni.

6. The improved passivation structure for GaN field effect transistor according to claim 1, wherein each of said at least one diffusion barrier metal layer is made of.

7. The improved passivation structure for GaN field effect transistor according to claim 1, wherein said high conductivity metal layer is made of at least one material selected from the group consisting of: Au, Al, and Cu.

8. The improved passivation structure for GaN field effect transistor according to claim 1, wherein said gate electrode further comprises an adhesion metal layer, wherein said adhesion metal layer is formed on said high conductivity metal layer.

9. The improved passivation structure for GaN field effect transistor according to claim 8, wherein said adhesion metal layer is made of at least one material selected from the group consisting of: Ti, TiW and TiN.

10. The improved passivation structure for GaN field effect transistor according to claim 1, wherein said semiconductor substrate is made of one material selected from the group consisting of: Si, SiC, Diamond, Sapphire and GaN.

11. The improved passivation structure for GaN field effect transistor according to claim 1, wherein each of said at least one dielectric layer has a thickness greater than or equal to 10 Å and less than or equal to 8000 Å.

12. The improved passivation structure for GaN field effect transistor according to claim 1, wherein said passivation layer has a thickness greater than or equal to 1 μm and less than or equal to 10 μm.

13. The improved passivation structure for GaN field effect transistor according to claim 1, wherein said wide bandgap epitaxial layer comprises a channel layer and a Schottky barrier layer, wherein said channel layer is formed on said semiconductor substrate, wherein said Schottky barrier layer is formed on said channel layer, wherein said Schottky contact metal layer is formed on said Schottky barrier layer.

14. The improved passivation structure for GaN field effect transistor according to claim 13, wherein said channel layer is made of GaN.

15. The improved passivation structure for GaN field effect transistor according to claim 13, wherein said Schottky barrier layer is made of at least one material selected from the group consisting of: AlGaN and GaN.

16. The improved passivation structure for GaN field effect transistor according to claim 13, wherein said Schottky barrier layer is made of at least one material selected from the group consisting of: AlGaN, GaN, InAlN and AlN.

17. The improved passivation structure for GaN field effect transistor according to claim 13, wherein said wide bandgap epitaxial layer further comprises a buffer layer, wherein said buffer layer is formed on said semiconductor substrate, said channel layer is formed on said buffer layer.

18. The improved passivation structure for GaN field effect transistor according to claim 17, wherein said buffer layer is made of GaN.

19. The improved passivation structure for GaN field effect transistor according to claim 17, wherein said wide bandgap epitaxial layer further comprises a cap layer, wherein said cap layer is formed on said Schottky barrier layer, said Schottky contact metal layer is formed on said cap layer.

20. The improved passivation structure for GaN field effect transistor according to claim 19, wherein said cap layer is made of at least one material selected from the group consisting of: GaN, AlGaN and AlN.

21. The improved passivation structure for GaN field effect transistor according to claim 13, wherein said wide bandgap epitaxial layer further comprises a cap layer, wherein said cap layer is formed on said Schottky barrier layer, said Schottky contact metal layer is formed on said cap layer.

22. The improved passivation structure for GaN field effect transistor according to claim 21, wherein said cap layer is made of at least one material selected from the group consisting of: GaN, AlGaN and AlN.

23. (canceled)

24. (canceled)

25. The improved passivation structure for GaN field effect transistor according to claim 1, wherein one of said at least one dielectric layer is made of silicon nitride with a thickness greater than or equal to 10 Å and less than or equal to 8000 Å.
